(19) United States
(12) Patent Application Publication
(10) Pub. No.: US 2024/0093350 A1
(43) Pub. Date: Mar. 21, 2024

(54) MASK FRAME ASSEMBLY, MASK ASSEMBLY AND DEPOSITION APPARATUS INCLUDING MASK ASSEMBLY

(71) Applicant: Samsung Display Co., Ltd., Yongin-si (KR)

(72) Inventors: SEUNGJU HONG, Yongin-si (KR); Mina WOO, Yongin-si (KR); JONGDAE LEE, Yongin-si (KR); SOOHYUN MIN, Yongin-si (KR); JONGSUNG PARK, Yongin-si (KR); MINCHUL SONG, Yongin-si (KR); WONYOUNG JANG, Yongin-si (KR)

(73) Assignee: Samsung Display Co., Ltd., Yongin-si (KR)

(21) Appl. No.: 18/332,895

(22) Filed: Jun. 12, 2023

(30) Foreign Application Priority Data
Sep. 21, 2022 (KR) 10-2022-0119623

(51) Int. Cl. C23C 14/04

(52) U.S. Cl. CPC C23C 14/044; H10K 71/166

(57) ABSTRACT

A mask frame assembly includes a mask frame including: a first surface including a first long side part extending in a first direction, a first short side part extending in a second direction intersecting the first direction, and a first recessed part extending in the first direction or the second direction, a second surface opposite to the first surface and including a second long side part extending in the first direction, a second short side part extending in the second direction, and a second recessed part disposed in the first direction or the second direction, a third surface connected to the first surface and the second surface and defining a frame opening part; a first support member disposed in the first recessed part; and a second support member disposed in the second recessed part.

### CROSS-REFERENCE TO RELATED APPLICATION(S)

This application claims priority to and benefits of Korean Patent Application No. 10-2022-0119623 under 35 U.S.C. § 119, filed on Sep. 21, 2022, the entire contents of which are incorporated hereby by reference.

### BACKGROUND

### 1. Technical Field

Embodiments relate to a mask frame assembly capable of controlling deformation of a mask frame, a mask assembly, and a deposition apparatus including the mask assembly.

### 2. Description of the Related Art

Display devices such as a television, a mobile phone, a tablet computer, a navigation device, and a game console, may each include a display panel for displaying an image. The display panel may include pixels. Each of the pixels may include a driving element such as a transistor, and a display element such as an organic light emitting diode. An electrode and a light emitting pattern may be deposited on a substrate to form the display element.

The light emitting pattern may be patterned by using a mask in which a deposition opening part is formed so as to be formed in a certain region. Recently, deposition process technologies by using a large-area mask are developed in order to improve production yield of the display panel. However, in case that the mask is not aligned at a position within a deposition apparatus, accuracy of the position at which the light emitting pattern is formed is reduced.

### SUMMARY

Embodiments provide a mask frame assembly capable of controlling deformation of a front portion or a rear portion of a mask frame through a plurality of support members disposed on the front portion or the rear portion of the mask frame, a mask assembly, and a deposition apparatus including the mask assembly.

Embodiments also provide a mask frame assembly capable of controlling deformation of a mask frame to ensure accuracy of a position at which a light emitting pattern is formed, a mask assembly including the mask frame assembly, and a deposition apparatus including the mask assembly.

However, embodiments of the disclosure are not limited to those set forth herein. The above and other embodiments will become more apparent to one of ordinary skill in the art to which the disclosure pertains by referencing the detailed description of the disclosure given below.

In an embodiment, a mask frame assembly may include a mask frame including a first surface including a first long side part extending in a first direction, a first short side part extending in a second direction intersecting the first direction, and a first recessed part extending along the first long side part in the first direction or extending along the first short side part in the second direction, a second surface opposite to the first surface and including a second long side part extending in the first direction, a second short side part extending in the second direction, and a second recessed part extending along the second long side part in the first direction or extending along the second short side part in the second direction, a third surface connected to the first surface and the second surface and defining a frame opening part, and a first support member disposed in the first recessed part and a second support member disposed in the second recessed part.

In an embodiment, the first recessed part may include a first inner groove spaced apart from the frame opening part by a distance, a first outer groove defined at opposite sides of the first inner groove, and a first step defined between the first inner groove and the first outer groove. The second recessed part may include a second inner groove spaced apart from the frame opening part by a distance, a second outer groove defined at opposite sides of the second inner groove, and a second step defined between the second inner groove and the second outer groove.

In an embodiment, a depth of the first inner groove and a depth of the second inner groove may be greater than or substantially equal to a depth of the first outer groove and a depth of the second outer groove, respectively.

In an embodiment, the first recessed part may include a plurality of first recessed parts or the second recessed part may include a plurality of second recessed parts, and the plurality of first recessed parts or the plurality of second recessed parts may be spaced apart from each other in a direction that is away from the frame opening part.

In an embodiment, the first recessed part and the second recessed part may not overlap each other on a cross section perpendicular to an extension direction of the first recessed part and the second recessed part.

In an embodiment, the first recessed part may be defined in the first short side part, and the second recessed part may be defined in the second short side part.

In an embodiment, the mask frame assembly may further include a third support member and a fourth support member. The first surface of the mask frame further may include a third recessed part accommodating the third support member and extending in a direction intersecting the first recessed part, and the second surface of the mask frame may further include a fourth recessed part accommodating the fourth support member and extending in the second surface in a direction intersecting the second recessed part.

In an embodiment, a width of the first recessed part and a width of the third recessed part may be different from each other, and a width of the second recessed part and a width of the fourth recessed part may be different from each other.

In an embodiment, a width of the first support member and a width of the third support member may be different from each other, and a width of the second support member and a width of the fourth support member may be different from each other.

In an embodiment, the mask frame may further include a fourth surface opposite to the third surface, the first surface may include a first part connected to the fourth surface, and a second part adjacent to the first part and including a portion bent to be connected to the third surface, and the first recessed part may be defined in the first part.

In an embodiment, a mask frame assembly may include a plurality of first support members and a plurality of second support members, a mask defining a deposition opening part, and a mask frame including a first surface facing the mask and including a first long side part extending in a first direction and a first short side part extending in a second direction intersecting the first direction and in which the plurality of first support members are disposed, a second surface opposite to the first surface and including a second long side part extending in the first direction and a second short side part which extends in the second direction and in which the plurality of second support members are disposed, and a third surface connected to the first surface and the second surface and defining a frame opening part overlapping the deposition opening part. A second recessed part may extend in the second direction, may accommodate the plurality of second support members, and may be defined in the second short side part.

In an embodiment, a first recessed part may extend in the second direction, may accommodate the plurality of first support members, and may be defined in the first short side part.

In an embodiment, a thickness of each of the plurality of first support members and a thickness of each of the plurality of second support members may be smaller than or substantially equal to a depth of the first recessed part and a depth of the second recessed part, respectively.

In an embodiment, the first recessed part may include a plurality of first steps spaced apart from each other in an extension direction of the first recessed part and coupled to the plurality of first support members.

In an embodiment, the second recessed part may include a plurality of second steps spaced apart from each other in an extension direction of the second recessed part and coupled to the plurality of second support members.

In an embodiment, the mask frame assembly may further include a plurality of third support members and a plurality of fourth support members. A third recessed part may extend in the first direction, may accommodate the plurality of third support members, and may be defined in the first long side part, and a fourth recessed part, which extends in the first direction and in which the plurality of fourth support members are disposed, may be defined in the second long side part.

In an embodiment, a width of the first recessed part and a width of the third recessed part may be different from each other, and a width of the second recessed part and a width of the fourth recessed part may be different from each other.

In an embodiment, the mask may include a plurality of mask members, and the plurality of mask members may be arranged in the first direction or the second direction to be disposed on the mask frame.

In an embodiment, the mask frame assembly may further include a plurality of spacing sticks disposed on the mask frame.

In an embodiment, a deposition apparatus may include a deposition chamber that provides an inner space, a mask frame including a first surface including a first long side part extending in a first direction and a first short side part extending in a second direction intersecting the first long side part, a second surface opposite to the first surface and including a second long side part extending in the first direction and a second short side part extending in the second direction intersecting the second long side part, and a third surface connected to the first surface and the second surface and defining a frame opening part, a deposition member disposed at a first side of the mask frame, a stage, which is disposed at a second side of the mask frame and supported by the second surface of the mask frame, a mask, which is disposed between the mask frame and the deposition member at the first side of the mask frame and supported by the first surface of the mask frame, and a first support member disposed in the first short side part and a second support member disposed in the second short side part.

In an embodiment, the first support member and the second support member may extend in the first direction.

In an embodiment, a first recessed part may accommodate the first support member, and may be defined in the first short side part, and a second recessed part may accommodate the second support member, and may be defined in the second short side part.

In an embodiment, a plurality of first steps may be coupled to the first support member, and may be defined in the first recessed part in an extension direction of the first recessed part, and a plurality of second steps may be coupled to the second support member, and may be defined in the second recessed part in an extension direction of the second recessed part.

In an embodiment, the deposition apparatus may further include a third support member extending in a direction intersecting the first direction, and disposed in the first long side part; and a fourth support member extending in a direction intersecting the first direction, and disposed in the second long side part.

In an embodiment, a third recessed part may accommodate the third support member, and may be defined in the first long side part, a fourth recessed part may accommodate the fourth support member, and may be defined in the second long side part. The third recessed part may include a plurality of third steps coupled to the third support member and disposed in an extension direction of the third recessed part, and the fourth recessed part may include a plurality of fourth steps coupled to the fourth support member and disposed in an extension direction of the fourth recessed part.

In an embodiment, an extension direction of the first short side part and the second short side part may have a tilt angle of about 45 degrees with respect to a normal direction to a bottom surface of the deposition chamber.

### BRIEF DESCRIPTION OF THE DRAWINGS

The accompanying drawings are included to provide a further understanding of the invention, and are incorporated in and constitute a part of this specification. The drawings illustrate embodiments and, together with the description, serve to explain principles of the invention. In the drawings:

FIG. 1 is a schematic cross-sectional view of a deposition apparatus according to an embodiment;

FIG. 2 is a schematic exploded perspective view of a portion of a deposition apparatus according to an embodiment;

FIG. 3 is a schematic exploded perspective view of a portion of a deposition apparatus according to an embodiment;

FIGS. 4A to 4C are schematic plan views of a mask frame according to an embodiment when viewed from the top;

FIGS. 5A and 5B are schematic plan views of a mask frame according to an embodiment when viewed from the bottom;

FIGS. 6A to 6C are schematic cross-sectional views of a side of a mask frame according to an embodiment;

FIG. 6D is a schematic cross-sectional view of another side of a mask frame according to an embodiment;

FIG. 7A is a schematic plan view of a mask frame according to an embodiment when viewed from the top;

FIG. 7B is a schematic cross-sectional view of a mask frame according to an embodiment;

FIG. 8A is a schematic plan view of a mask frame according to an embodiment when viewed from the top;

FIG. 8B is a schematic cross-sectional view of a mask frame according to an embodiment; and

FIGS. 9A and 9B are schematic views illustrating a method for controlling anti-deformation of a mask frame according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

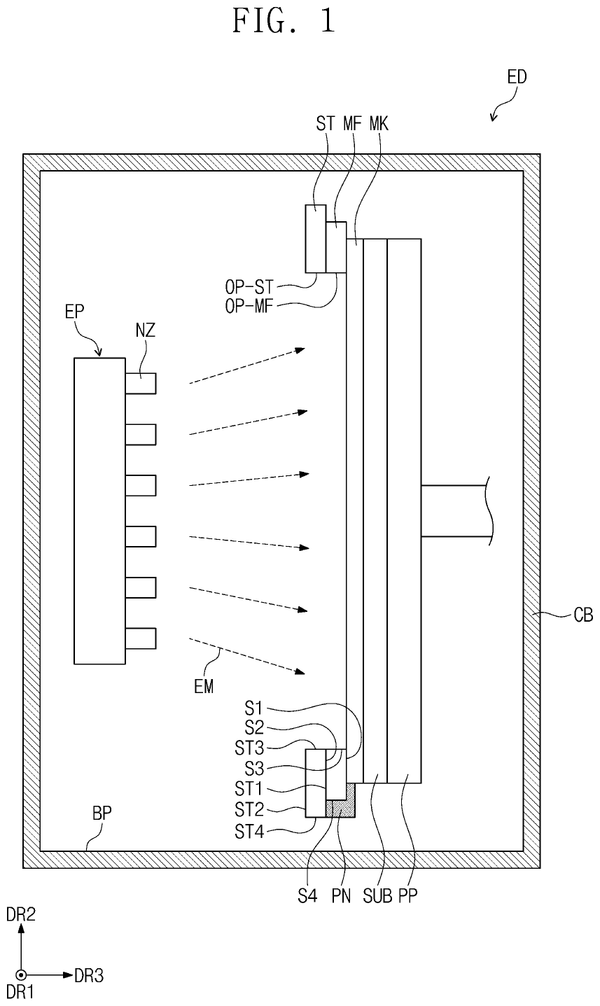

FIG. 1 is a schematic cross-sectional view of a deposition apparatus according to an embodiment.

Referring to FIG. 1, a deposition apparatus ED may include a deposition chamber CB, a deposition member EP, a fixing member PP, a mask MK, a mask frame MF, a stage ST, and an external force applying member PN. The deposition apparatus ED may further include an additional mechanical apparatus for implementing an inline system. The deposition apparatus ED may be used in forming at least some of functional layers included in a display panel.

The deposition chamber CB may provide an inner space. The deposition member EP, the fixing member PP, the mask MK, the mask frame MF, the stage ST, and the external force applying member PN may be disposed in the inner space of the deposition chamber CB. In the deposition chamber CB, a sealed space may be defined, and a deposition condition may be set to a vacuum. The deposition chamber CB may include at least one gate, and the deposition chamber CB may be opened and closed by the gate. The mask MK, the mask frame MF, and a substrate SUB may enter and exit the deposition chamber CB through the gate provided in the deposition chamber CB.

The deposition member EP may include a bottom surface BP, a ceiling surface, and side walls. The bottom surface BP, the ceiling surface, and the side walls may form the deposition chamber CB in the form of a box. The bottom surface BP of the deposition chamber CB may be parallel to a plane defined by a first direction DR1 and a third direction DR3, and a normal direction to the bottom surface BP of the deposition chamber CB may be parallel to a second direction DR2. The second direction DR2 may be parallel and opposite to the gravity direction. In the description, the state “in a plan view” may be set based on a plane parallel to a plane defined by the first direction DR1 and the second direction DR2.

The fixing member PP may be disposed above the deposition member EP inside the deposition chamber CB. The fixing member PP may fix the substrate SUB on the mask MK. The fixing member PP may include a jig or a robot arm that holds the mask MK. The fixing member PP may include magnetic substances that function the mask MK and the substrate SUB to be in close contact with each other. For example, the magnetic substances may generate a magnetic force to fix the mask MK, and the substrate SUB disposed between the mask MK and the fixing member PP may be in close contact with the mask MK.

The substrate SUB may be a workpiece on which a deposition material EM is deposited. The substrate SUB may include a support substrate SUB and a synthetic resin layer disposed on the support substrate SUB. The support substrate SUB may be removed in the later step of a display panel manufacturing process.

The deposition member EP may be disposed to face the fixing member PP inside the deposition chamber CB. The deposition member EP may include a space, in which the deposition material EM is accommodated, and at least one nozzle NZ. The deposition material EM may include an inorganic material, a metal, or an organic material, which is sublimated or vaporized. For example, the deposition material EM may include an organic light emitting material for forming a light emitting layer. However, the deposition material EM is not limited to the examples above. The deposition material EM sublimated or vaporized may be sprayed toward the substrate SUB through the nozzle NZ. The deposition material EM may pass through the mask MK to be deposited on the substrate SUB in a certain pattern.

The stage ST may be disposed between the deposition member EP and the fixing member PP, and the mask frame MF may be disposed between the stage ST and the fixing member PP. The stage ST may be coupled to the mask frame MF to support the mask frame MF.

The stage ST may include a front surface ST1, a rear surface ST2, an inner side surface ST3, and an outer side surface ST4. The rear surface ST2 may be a surface facing the deposition member EP. The front surface ST1 may be a surface facing the mask frame MF. A stage opening part OP-ST may be disposed in the inner side surface ST3 of the stage ST.

The front surface ST1 of the stage ST may be substantially perpendicular to the bottom surface BP of the deposition chamber CB. For example, the front surface ST1 of the stage ST may be substantially parallel to the normal direction to the bottom surface BP of the deposition chamber CB. The front surface ST1 of the stage ST may be inclined with respect to a direction perpendicular to the bottom surface BP of the deposition chamber CB. The front surface ST1 of the stage ST may be spaced apart from the bottom surface BP of the deposition chamber CB by a certain interval (or distance). Accordingly, respective rear surfaces of the mask frame MF and the mask MK, which are disposed on the front surface ST1 of the stage ST, may be substantially perpendicular to the bottom surface BP of the deposition chamber CB to perform a deposition process. Accordingly, the mask MK having a large area may be prevented from sagging (or bending) by gravity, and the deposition reliability may be improved.

However, embodiments are not limited thereto, and the front surface ST1 of the stage ST may be inclined at a certain angle with respect to the direction perpendicular to the bottom surface BP of the deposition chamber CB. For example, the mask MK having a large area may be prevented from sagging (or bending) by gravity, and the deposition reliability may be improved like the case in which the front surface ST1 of the stage ST is substantially perpendicular to the bottom surface BP of the deposition chamber CB. In an embodiment, the front surface ST1 of the stage ST may have a tilt angle of about 45 degrees or less with respect to the direction perpendicular to the bottom surface BP of the deposition chamber CB.

In another example, the front surface ST1 of the stage ST may be substantially parallel to the bottom surface BP of the deposition chamber CB, and the respective rear surfaces of the mask frame MF and the mask MK may be substantially parallel to the bottom surface BP of the deposition chamber CB to perform the deposition process.

In an embodiment, the inner side surface ST3 of the stage ST may be a surface perpendicular to the front surface ST1 or the rear surface ST2.

The mask frame MF may be disposed between the stage ST and the fixing member PP, and the mask MK may be disposed between the mask frame MF and the fixing member PP. The mask frame MF may be coupled to the mask MK to support the mask MK. The mask frame MF may include portions that define a frame opening part OP-MF. For example, the mask frame MF may have a frame shape that surrounds the frame opening part OP-MF in a plan view.

The mask frame MF may include a first surface S1 to a fourth surface S4.

The first surface S1 may define a top surface of the mask frame MF. The first surface S1 may be a surface on which the mask MK is disposed. A second surface S2 may define a bottom surface of the mask frame MF. The second surface S2 may oppose the first surface S1. The second surface S2 may be a surface facing the stage ST and facing the deposition member EP.

A third surface S3 may define an inner side surface of the mask frame MF. The third surface S3 may be bent from a side of the first surface S1 to be connected to a side of the second surface S2. The fourth surface S4 may define an outer side surface of the mask frame MF. The fourth surface S4 may be bent from another side of the first surface S1 to be connected to the another side of the second surface S2.

The third surface S3 may define the frame opening part OP-MF. The frame opening part OP-MF may overlap a deposition opening part OP-MK or the stage opening part OP-ST on a plane defined by the first direction DR1 and the second direction DR2.

In an embodiment, the third surface S3 may be a surface perpendicular to the first surface S1 or the second surface S2.

In the mask frame MF disposed on the stage ST, the first surface S1 and the second surface S2 of the mask frame MF may be inclined at a certain angle with respect to the direction perpendicular to the bottom surface BP of the deposition chamber CB. The mask frame MF may prevent the mask MK having a large area from sagging (or bending) by gravity, and may improve the deposition reliability like the case in which the first surface S1 and the second surface S2 are substantially perpendicular to the bottom surface BP of the deposition chamber CB.

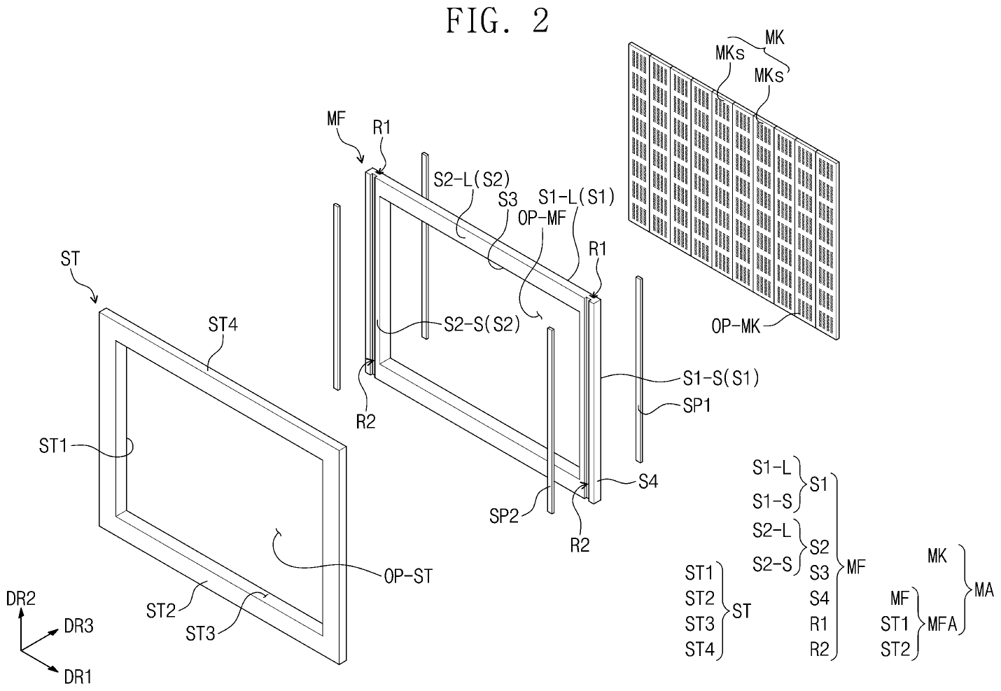

In an embodiment, a first long side part S1-L (see FIG. 2) disposed in the first surface S1 and a second long side part S2-L (see FIG. 2) disposed in the second surface S2, which will be described below, may each have a tilt angle of about 45 degrees or less with respect to the direction perpendicular to the bottom surface BP of the deposition chamber CB.

The mask MK may include the deposition opening part OP-MK that defines a deposition area. The mask MK may be disposed so that the deposition opening part OP-MK may be disposed to overlap each of the stage opening part OP-ST and the frame opening part OP-MF. The mask MK may be disposed on the first surface S1 of the mask frame MF to be supported by the first surface S1.

The external force applying member PN may be disposed on the stage ST and may support the mask frame MF. The external force applying member PN may be disposed below of the stage ST on a plane defined by the first direction DR1 and the second direction DR2. The external force applying member PN may be disposed to face the fourth surface S4 of the mask frame MF, which is adjacent to the bottom surface BP of the deposition chamber CB. The external force applying member PN may support a lower side of the mask frame MF and move in the second direction DR2. As the external force applying member PN moves in the second direction DR2, an external force applied to the mask frame MF may be adjusted. The external force applying member PN may compensate for deformation of the mask frame MF, which is caused by an intrinsic tension of the mask frame MF.

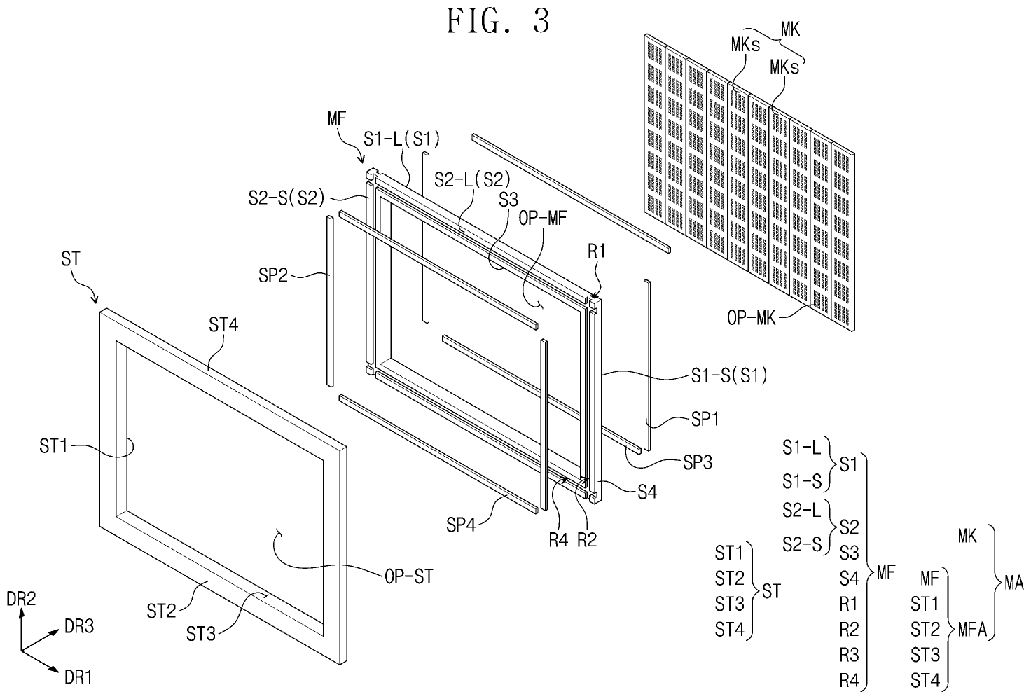

FIG. 2 is a schematic exploded perspective view of a portion of a deposition apparatus according to an embodiment. FIG. 3 is a schematic exploded perspective view of a portion of a deposition apparatus according to an embodiment.

Referring to FIGS. 2 and 3, a stage ST, a mask frame MF, and a mask MK may be disposed in sequence. The mask MK may be disposed so that a deposition opening part OP-MK may be disposed to overlap each of the stage opening part OP-ST and the frame opening part OP-MF.

The same components as (or similar components to) those described with reference to FIG. 1 are denoted as the same/similar reference numbers or symbols, and redundant description is omitted for descriptive convenience.

A mask assembly MA may include the mask MK and a mask frame assembly MFA. The mask frame assembly MFA may include the mask frame MF and support members SP1, SP2, SP3 and SP4.

The mask MK may include mask members MKs. The mask members MKs may be disposed on a first surface S1 of the mask frame MF in the first direction DR1 or the second direction DR2. For example, the deposition opening part OP-MK may be provided in plurality, and each of the deposition opening parts OP-MK may be formed in each of the mask members MKs.

The support members SP1, SP2, SP3 and SP4 may be disposed between the stage ST and the mask frame MF or between the mask frame MF and the mask MK.

The stage ST may have an inner side surface ST3 connecting between a front surface ST1 and a rear surface ST2. A minimum angle between the front surface ST1 and the inner side surface ST3 that are connected to each other may be less than about 90 degrees. A minimum angle between the rear surface ST2 and the inner side surface ST3 that are connected to each other may be greater than about 90 degrees and less than about 180 degrees. Accordingly, the stage opening part OP-ST formed in the inner side surface ST3 of the stage ST may have an inner diameter that decreases as being farther away from a deposition member EP in the third direction DR3.

However, embodiments are not limited thereto, and the inner side surface ST3 of the stage ST may be perpendicular to the front surface ST1 or the rear surface ST2.

The mask frame MF may have a third surface S3 inclined with respect to the first surface S1 or a second surface S2. A minimum angle between the first surface S1 and the third surface S3 that are connected to each other may be less than about 90 degrees. A minimum angle between the second surface S2 and the third surface S3 that are connected to each other may be greater than about 90 degrees and less than about 180 degrees. Accordingly, the frame opening part OP-MF formed in the mask frame MF may have an inner diameter that decreases as being farther away from the deposition member EP in the third direction DR3.

However, embodiments are not limited thereto, and the third surface S3 may be perpendicular to the first surface S1 or the second surface S2.

The first surface S1 of the mask frame MF may include a first long side part S1-L extending in the first direction DR1 and a first short side part S1-S extending in the second direction DR2. The first long side part S1-L may have a length greater than or substantially equal to that of the first short side part S1-S, and a specific value may vary according to the design.

The second surface S2 of the mask frame MF may include a second long side part S2-L extending in the first direction DR1 and a second short side part S2-S extending in the second direction DR2. Likewise, the second long side part S2-L may have a length greater than or substantially equal to that of the second short side part S2-S, and a specific value may vary according to the design.

The support members SP1, SP2, SP3 and SP4 may be provided in plurality and disposed in the first surface S1 or the second surface S2 of the mask frame MF. The support members SP1, SP2, SP3 and SP4 may include an invar material.

The support members SP1 and SP2 may include a first support member SP1 disposed on the first surface S1 and a second support member SP2 disposed on the second surface S2. The first support member SP1 may be disposed on the first surface S1 of the mask frame MF to support the first surface S1, and the second support member SP2 may be disposed on the second surface S2 of the mask frame MF to support the second surface S2.

As first and second support members SP1 and SP2 are disposed on the first surface S1 and the second surface S2 of the mask frame MF to support the first surface S1 and the second surface S2, respectively, the deformation of the mask frame MF, which may occur in the mask frame MF during vertical loading of the mask frame MF, may be controlled.

According to an embodiment, the first support member SP1 may support the first short side part S1-S of the first surface S1, and the second support member SP2 may support the second short side part S2-S of the second surface S2.

A first recessed part R1 and a second recessed part R2 extending in the first direction DR1 or the second direction DR2 may be formed in the mask frame MF. For example, the first recessed part R1 extending in the first direction DR1 or the second direction DR2 may be formed in the first surface S1 of the mask frame MF, and the second recessed part R2 in the first direction DR1 or the second direction DR2 may be formed in the second surface S2. The first recessed part R1 and the second recessed part R2 may be recessed in the first surface S1 and the second surface S2, respectively.

The first support member SP1 may be accommodated (or disposed) in the first recessed part R1 formed in the first surface S1 of the mask frame MF, and the second support member SP2 may be accommodated (or disposed) in the second recessed part R2 disposed in the second surface S2 of the mask frame MF. The first support member SP1 may be accommodated in the first recessed part R1 to support the first surface S1, and the second support member SP2 may be accommodated in the second recessed part R2 to support the second surface S2.

The first and second support members SP1 and SP2 may be accommodated in the first recessed part R1 and the second recessed part R2 to support the first surface S1 and the second surface S2, respectively, so that a deformation control force for the first surface S1 and the second surface S2 may be improved through the support members (e.g., SP1 and SP2).

Referring to FIG. 2, the first recessed part R1 may be formed in the first short side part S1-S of the first surface S1 of the mask frame MF, and the second recessed part R2 may be formed in the second short side part S2-S of the second surface S2 of the mask frame MF. The first support member SP1 may be accommodated in the first recessed part R1 to support the first short side part S1-S, and the second support member SP2 may be accommodated in the second recessed part R2 to support the second short side part S2-S.

Referring to FIG. 3, the support members SP1, SP2, SP3 and SP4 may include a third support member SP3 disposed on the first long side part S1-L of the first surface S1 and a fourth support member SP4 disposed on the second long side part S2-L of the second surface S2. The third support member SP3 may be disposed on the first long side part S1-L to support the first long side part S1-L, and the fourth support member SP4 may be disposed on the second long side part S2-L to support the second long side part S2-L.

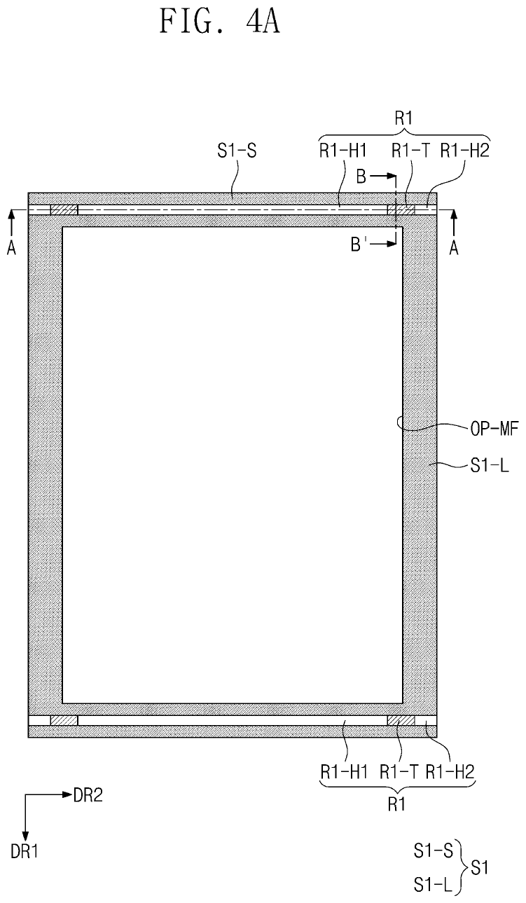

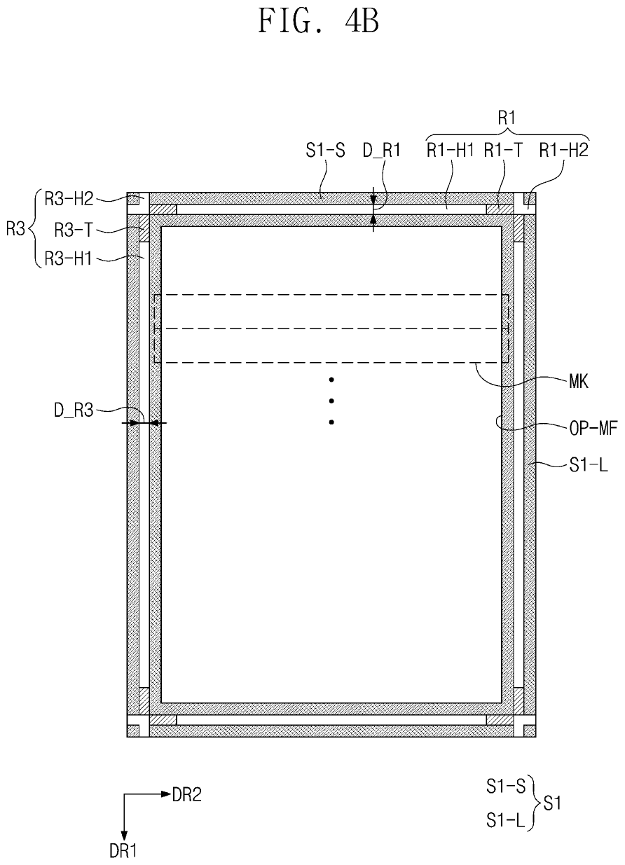

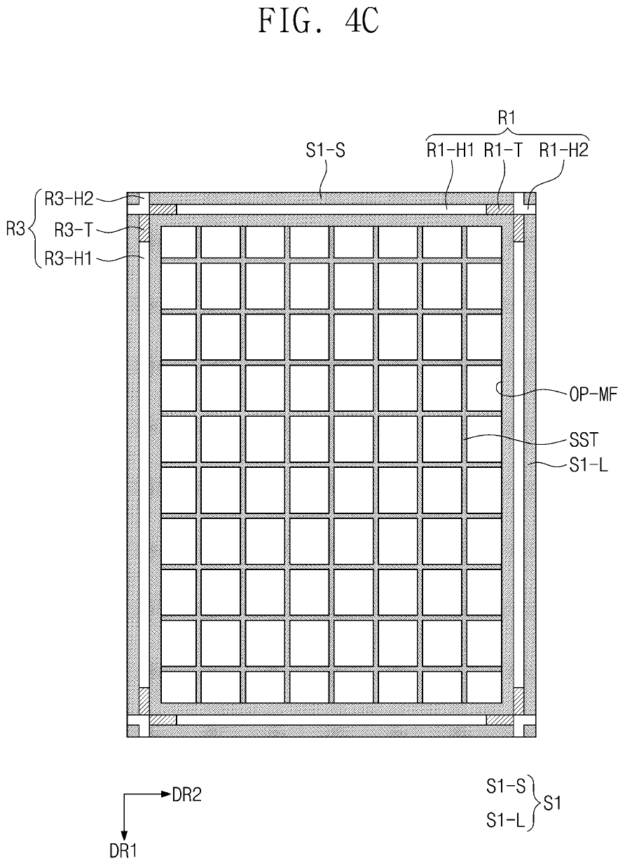

A third recessed part R3 (see FIG. 4B) and a fourth recessed part R4 may be formed in the mask frame MF. For example, the third recessed part R3 may be formed in the first surface S1 of the mask frame MF in a direction intersecting an extension direction of the first recessed part R1, and the fourth recessed part R4 may be formed in the second surface S2 in a direction intersecting an extension direction of the second recessed part R2. The third recessed part R3 may be recessed in the first surface S1, and the fourth recessed part R4 may recessed in the second surface S2.

The third support member SP3 may be accommodated (or disposed) in the third recessed part R3 formed in the first surface S1 of the mask frame MF, and the fourth support member SP4 may be accommodated in the fourth recessed part R4 disposed in the second surface S2 of the mask frame MF. The third support member SP3 may be accommodated in the third recessed part R3 to support the first surface S1, and the fourth support member SP4 may be accommodated (or disposed) in the fourth recessed part R4 to support the second surface S2.

Referring to FIG. 3, the third recessed part R3 may be formed in the first long side part S1-L of the first surface S1 of the mask frame MF, and the fourth recessed part R4 may be formed in the second long side part S2-L of the second surface S2 of the mask frame MF. The third support member SP3 may be accommodated in the third recessed part R3 to support the first long side part S1-L, and the fourth support member SP4 may be accommodated in the fourth recessed part R4 to support the second long side part S2-L.

FIGS. 4A, 4B, and 4C are schematic plan views of a mask frame according to an embodiment when viewed from the top.

Referring to FIG. 4A, the first recessed part R1 may be formed in the first short side part S1-S of the first surface S1 of the mask frame MF.

The first recessed part R1 may include a first inner groove R1-H1, a first step R1-T, and a first outer groove R1-H2.

The first inner groove R1-H1 of the first recessed part R1 may be spaced a certain distance from the frame opening part OP-MF. The first outer groove R1-H2 may be formed (or disposed) at each of sides (e.g., opposite sides) of the first inner groove R1-H1. The first step R1-T may be disposed between the first inner groove R1-H1 and the first outer groove R1-H2.

The first inner groove R1-H1 and the first outer groove R1-H2 may be recessed in a normal direction to the first surface S1. The first step R1-T may protrude in the normal direction to the first surface S1.

According to an embodiment, the first recessed part R1 may be formed in the first short side part S1-S of the first surface S1, and the second recessed part R2 may be formed in the second short side part S2-S of the second surface S2. However, embodiments are not limited thereto, and the second recessed part R2 and the fourth recessed part R4 may be formed in the second surface S2.

Referring to FIG. 4B, the first recessed part R1 may be formed in the first short side part S1-S of the first surface S1 of the mask frame MF, and the third recessed part R3 may be formed in the first long side part S1-L of the first surface S1.

For descriptive convenience, a portion of the mask MK coupled to the mask frame MF is illustrated with dotted lines. The first recessed part R1 and the third recessed part R3 may be formed (or disposed) at a position spaced apart from a region in which the mask MK and the mask frame MF overlap each other, and may not overlap on a plan view. Accordingly, an interference between the mask MK and the first support member SP1 to be accommodated in the first recessed part R1 may be prevented, and an interference between the mask MK and the third support member SP3 to be accommodated in the third recessed part R3 may be prevented.

The length of the third recessed part R3 in an extension direction (e.g., first direction DR1) may be greater than the length of the first recessed part R1 in an extension direction (e.g., second direction DR2). However, embodiments are not limited thereto, and the length of the third recessed part R3 in the extension direction may be substantially equal to the length of the first recessed part R1 in the extension direction.

The third recessed part R3 may also include a third inner groove R3-H1, a third step R3-T, and a third outer groove R3-H2 like the first recessed part R1 described above may include the first inner groove R1-H1, the first step R1-T, and the first outer groove R1-H2. The third inner groove R3-H1 may be spaced a certain distance from the frame opening part OP-MF. The third outer groove R3-H2 may be formed (or disposed) at each of sides (e.g., opposite sides) of the third inner groove R3-H1. The third step R3-T may be disposed between the third inner groove R3-H1 and the third outer groove R3-H2.

According to an embodiment, a width D_R1 of the first recessed part R1 in the first direction DR1 may be different from a width D_R3 of the third recessed part R3 in the second direction DR2. For example, a width D_R1 of the first recessed part R1 may be smaller than or substantially equal to a width D_R3 of the third recessed part R3.

Accordingly, the width of the first support member SP1 (see FIG. 3) accommodated in the first recessed part R1 may be smaller than or substantially equal to the width of the third support member SP3 (see FIG. 3) accommodated in the third recessed part R3. For example, a size relationship between the widths of the first support member SP1 and the third support member SP3 may correspond to a size relationship between the widths of the first recessed part R1 and the third recessed part R3.

However, embodiments are not limited thereto, and the width of the first support member SP1 may be smaller than or substantially equal to the width of the third support member SP3 irrespective of a width relationship between the first recessed part R1 and the third recessed part R3.

According to an embodiment, in the first surface S1, the first recessed part R1 may be formed in the first short side part S1-S and the third recessed part R3 may be formed in the first long side part S1-L, and, in the second surface S2, the second recessed part R2 may be formed in the second short side part S2-S. However, embodiments are not limited thereto, and may include various embodiments such as an embodiment in which the second recessed part R2 and the fourth recessed part R4 are formed in the second surface S2. Embodiments are not limited thereto.

Referring to FIG. 4C, a support member may be disposed on the mask frame MF. The same components as (similar components to) those described with reference to FIGS. 4A and 4B are denoted as the same/similar reference numbers or symbols, and redundant description is omitted for descriptive convenience.

A spacing stick SST may be provided in plurality, and the spacing sticks SST may be spaced a certain gap from each other to be disposed on the mask frame MF. The mask MK may be disposed on the spacing sticks SST to prevent the mask MK from sagging (or bending) without being fixed on the mask frame MF, so that spacings between the mask MK and the mask frame MF may be filled to prevent organic matters from being deposited on the substrate SUB due to the spacings unlike the design.

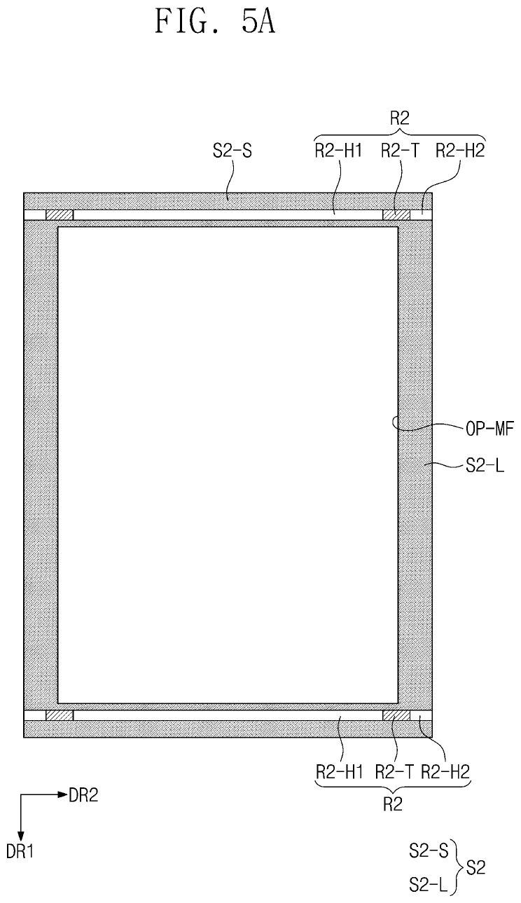

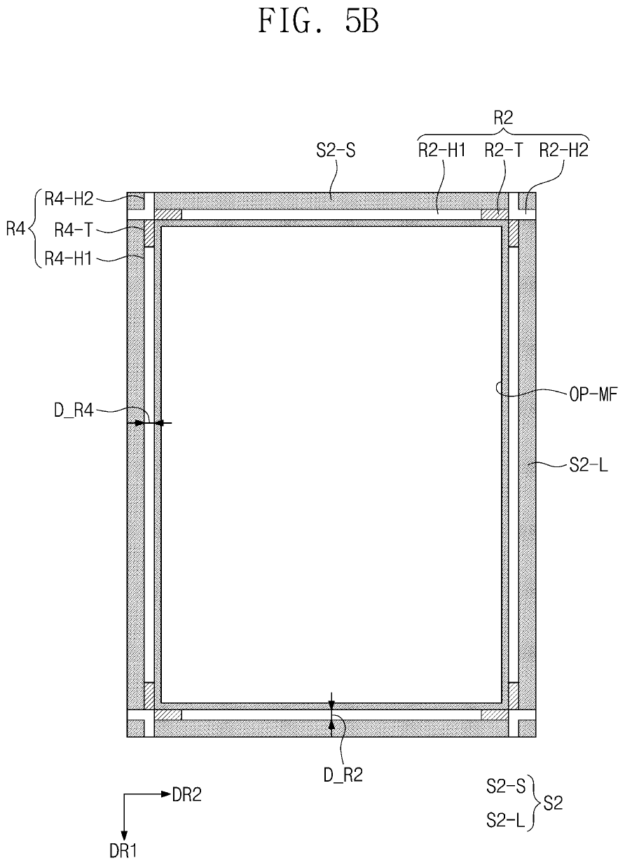

FIG. 5A is a schematic plan view of a mask frame according to an embodiment when viewed from the bottom. FIG. 5B is a schematic plan view of a mask frame according to an embodiment when viewed from the bottom.

Referring to FIG. 5A, the second recessed part R2 may be formed in the second short side part S2-S of the second surface S2 of the mask frame MF.

The second recessed part R2 may include a second inner groove R2-H1, a second step R2-T, and a second outer groove R2-H2.

The second inner groove R2-H1 may be spaced a certain distance from the frame opening part OP-MF. The second outer groove R2-H2 may be formed (or disposed) at each of sides (e.g., opposite sides) of the second inner groove R2-H1. The second step R2-T may be disposed between the second inner groove R2-H1 and the second outer groove R2-H2. The depth of the second inner groove R2-H1 may be greater than or substantially equal to the depth of the second outer groove R2-H2.

Referring to FIG. 5B, the second surface S2 of the mask frame MF, the second recessed part R2 may be formed in the second short side part S2-S and the fourth recessed part R4 may be formed in the second long side part S2-L.

The length of the fourth recessed part R4 in an extension direction (e.g., first direction DR1) may be greater than the length of the second recessed part R2 in an extension direction (e.g., second direction DR2). However, embodiments are not limited thereto, and the length of the fourth recessed part R4 in the extension direction may be substantially equal to the length of the second recessed part R2 in the extension direction.

A width D_R2 of the second recessed part R2 may be smaller than or substantially equal to a width D_R4 of the fourth recessed part R4. Accordingly, the width of the second support member SP2 accommodated in the second recessed part R2 may be smaller than or substantially equal to the width of the fourth support member SP4 accommodated in the fourth recessed part R4.

The fourth recessed part R4 may also include a fourth inner groove R4-H1 spaced a certain distance from the frame opening part OP-MF, a fourth outer groove R4-H2 formed (or disposed) at each of sides (e.g., opposite sides) of the fourth inner groove R4-H1, and a fourth step R4-T disposed between the fourth inner groove R4-H1 and the fourth outer groove R4-H2.

According to an embodiment, in case that the second surface S2 of the mask frame MF includes the second recessed part R2 formed in the second short side part S2-S as illustrated in FIG. 5A, the first surface S1 of the mask frame MF may include the first recessed part R1 formed in the first short side part S1-S of the first surface S1 as illustrated in FIG. 4A. In another example, as illustrated in FIG. 4B, the first surface S1 of the mask frame MF may include the first recessed part R1 formed in the first short side part S1-S of the first surface S1, and the third recessed part R3 in the first long side part S1-L.

The second surface S2 of the mask frame MF is not limited to that illustrated in FIG. 5A. Like that illustrated in FIG. 5B, the second recessed part R2 may be formed in the second short side part S2-S, and the fourth recessed part R4 may be formed in the second long side part S2-L. For example, the first surface S1 may be the same as that illustrated in FIG. 4A or 4B.

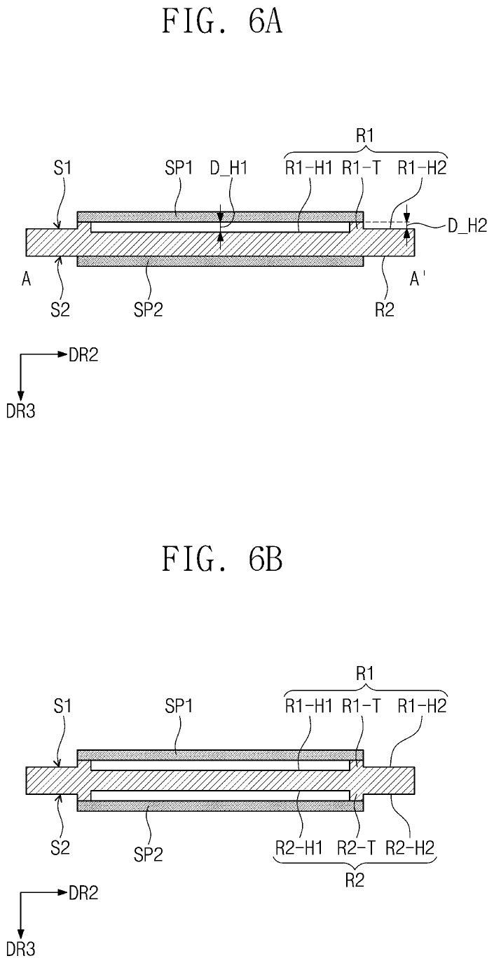

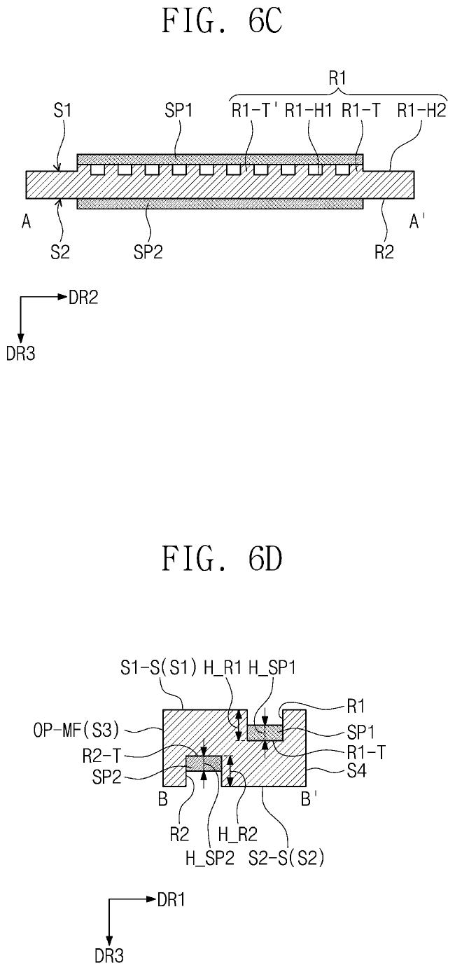

FIGS. 6A to 6D are schematic cross-sectional views of a mask frame according to an embodiment.

The same components as (or similar components to) those described with reference to FIGS. 1 to 5 are denoted as the same/similar reference numbers or symbols, and redundant description is omitted for descriptive convenience.

FIG. 6A is a schematic view illustrating a portion of the mask MK taken along line A-A′ illustrated in FIG. 4A.

Referring to FIG. 6A, a first recessed part R1 may be formed in a first surface S1 of the mask frame MF, and a second recessed part R2 may be formed in a second surface S2. The first recessed part R1 of the first surface S1 may include the first inner groove R1-H1, the first step R1-T, and the first outer groove R1-H2 that are described above.

The first inner groove R1-H1 and the second outer groove R1-H2 may be recessed in a normal direction to the first surface S1. The first step R1-T may protrude in the normal direction to the first surface S1.

A depth D_H1 of the first inner groove R1-H1 in the normal direction to the first surface S1 may be greater than or substantially equal to a depth D_H2 of the first outer groove R1-H2 in the normal direction to the first surface S1. For example, a depth D_H1 of the first inner groove R1-H1 may be greater than or substantially equal to a depth D_H2 of the first outer groove R1-H2.

As the first support members SP1 each are accommodated in the first recessed part R1 of the first surface S1 to support the first surface S1, the deformation of the mask frame MF that may occur in the mask frame MF during the vertical loading of the mask frame MF may be controlled.

The first support member SP1 may be coupled and fixed to the first step R1-T. The first support member SP1 may be coupled and fixed to the first step R1-T to improve the deformation controlling force of the first support member SP1 for a second surface S2.

In an example, the first support member SP1 may be coupled to the first step R1-T by welding. However, embodiments are not limited thereto. The first support member SP1 may be coupled and fixed to the first step R1-T using various methods, and embodiments are not limited thereto.

The first support member SP1 may be coupled and fixed to the first step R1-T by applying a force to the first support member SP1 in an extension direction of the first support member SP1 to increase tension of the first support member SP1. In case that the first support member SP1 is inserted into the first recessed part R1 and coupled and fixed to the first step R1-T, the first support member SP1 may contract in the extension direction.

Accordingly, the deformation of the mask frame MF that has occurred in the mask frame MF may be controlled. For example, the first support member SP1 may effectively control the deformation of the mask frame MF bent (or curved) in a direction opposite to the normal direction to the first surface S1.

Referring to FIG. 6B, a first recessed part R1 including a first inner groove R1-H1, a first step R1-T, and a first outer groove R1-H2 may be formed in a first surface S1 of the mask frame MF, and a second recessed part R2 including a second inner groove R2-H1, a second step R2-T, and a second outer groove R2-H2 may be formed in a second surface S2 of the mask frame MF.

A first support member SP1 may be coupled and fixed to the first step R1-T, and a second support member SP2 may be coupled and fixed to the second step R2-T. As described above, the first support member SP1 and the second support member SP2 may be coupled and fixed to the first step R1-T and the second step R2-T, respectively, in a state in which tension increases by application of a force in an extension direction thereof. Thereafter, the first support member SP1 and the second support member SP2 may contract in the extension direction. The first support member SP1 may effectively control the deformation of the mask frame MF bent (or curved) in a direction opposite to a normal direction to the first surface S1, and the second support member SP2 may effectively control the deformation of the mask frame MF bent (or curved) in a normal direction to the second surface S2.

Referring to FIG. 6C, a first recessed part R1 may include sub-steps R1-T′ in an extension direction. The length of each of the sub-steps R1-T′ in a normal direction to a first surface S1 may correspond to the length of a first step R1-T in the normal direction to the first surface S1. For example, the height of the sub-step R1-T′ may be substantially equal to the height of the first step R1-T.

A first support member SP1 may be coupled and fixed also to sub-steps R1-T′ to further improve the deformation controlling force of the first support member SP1 for the mask frame MF.

FIG. 6D is a schematic view illustrating a portion of the mask MK taken along line B-B′ illustrated in FIG. 4A.

Referring to FIG. 6D, according to an embodiment, a first recessed part R1 may be formed in a first surface S1 of the mask frame MF, and a second recessed part R2 may be formed in a second surface S2. The first recessed part R1 of the first surface S1 and the second recessed part R2 of the second surface S2 may include the first and second inner grooves R1-H1 and R2-H1, the first and second steps R1-T and R2-T, and the first and second outer grooves R1-H2 and R2-H2, respectively, which are described above.

A first support member SP1 may be accommodated (e.g., fully accommodated) in the first recessed part R1, and a second support member SP2 may be accommodated (e.g., fully accommodated) in the second recessed part R2. For example, a thickness H_SP1 of the first support member SP1 in a normal direction to the first surface S1 may be smaller than or substantially equal to a depth H_R1 of the first recessed part R1 in the normal direction to the first surface S1. For example, a thickness H_SP1 of the first support member SP1 may be smaller than or substantially equal to a minimum depth of the first recessed part R1.

For example, in a state in which the first support member SP1 is coupled and fixed to a first step R1-T, the first support member SP1 may be accommodated (e.g., fully accommodated) in the first recessed part R1 so that at least a portion of the first support member SP1 may not protrude to the outside of the first recessed part R1.

Accordingly, the structure of the mask assembly MA may be maintained without deformation in shapes of the existing mask MK and stage ST. For example, the configuration of the existing deposition apparatus ED may be utilized as it is, and thus the economic efficiency may be ensured.

Likewise, also in a second support member SP2 and a second recessed part R2, a thickness H_SP2 of the second support member SP2 may be smaller than or substantially equal to a depth H_R2 of the second recessed part R2. For example, the thickness of the second support member SP2 may be smaller than or substantially equal to a minimum depth of the second recessed part R2.

The first recessed part R1 and the second recessed part R2 may not overlap each other on a cross section perpendicular to an extension direction of the first recessed part R1 and the second recessed part R2. In an example, in case that the first recessed part R1 and the second recessed part R2 extend in the second direction DR2, the first recessed part R1 and the second recessed part R2 may not overlap each other on a cross section perpendicular to the second direction DR2.

As the first recessed part R1 and the second recessed part R2 do not overlap each other on the cross section perpendicular to the extension direction, the mask frame MF may be prevented from being thinned to a certain thickness or less. Accordingly, the deformation of the mask MK may be prevented from readily occurring during the manufacture or vertical loading of the mask frame MF.

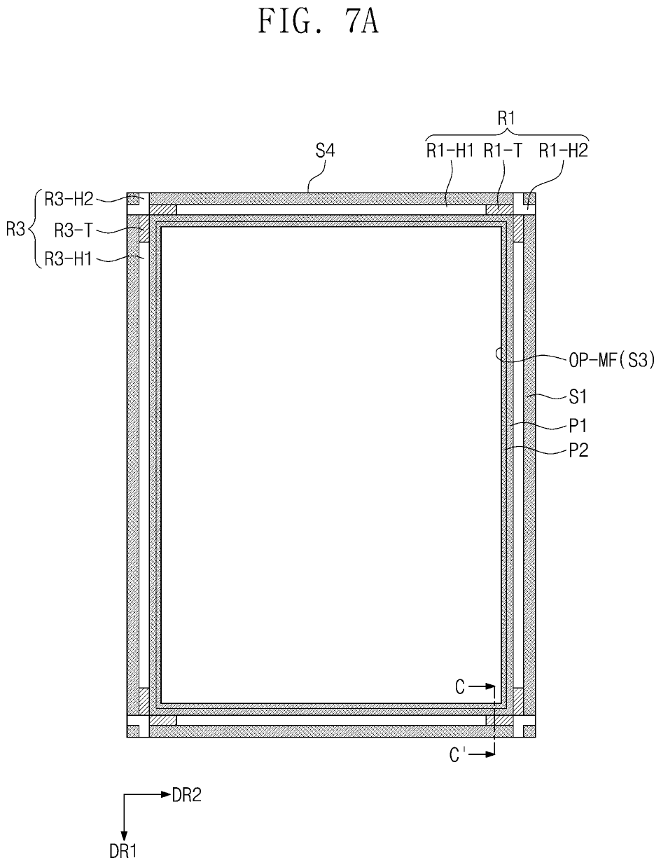

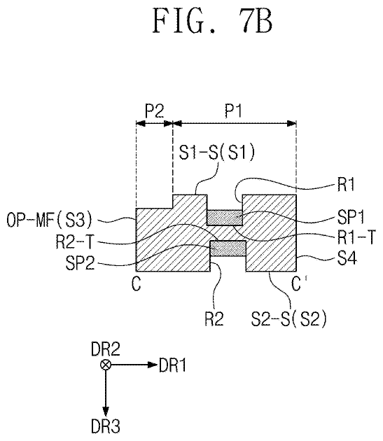

FIG. 7A is a schematic plan view of a mask frame according to an embodiment when viewed from the top. FIG. 7B is a schematic cross-sectional view of a mask frame according to an embodiment.

The same components as (or similar components to) those described with reference to FIG. 4 are denoted as the same/similar reference numbers or symbols, and redundant description is omitted for descriptive convenience.

Referring to FIG. 7A, a mask frame MF may include a first part P1 and a second part P2.

The first part P1 and the second part P2 are disposed adjacent to each other within a first surface S1. The first part P1 and the second part P2 may not overlap each other within the first surface S1.

The first part P1 may be connected to a fourth surface S4, and the second part P2 may be adjacent to the first part P1 and may have a portion bent to be connected to a third surface S3. The second part P2 may be a part on which the mask MK (see FIG. 2) is disposed.

As illustrated in the drawing, a first recessed part R1 and a third recessed part R3 may be formed in the first part P1. In case that the first recessed part R1 and the third recessed part R3 are formed in the first part P1 and the mask MK is disposed on the mask frame MF, the mask MK may be prevented from being separated from a position without being fixed due to an occurrence of an interference.

FIG. 7B is a schematic view illustrating a portion of the mask frame MF taken along line C-C′ illustrated in FIG. 7A.

Referring to FIG. 7B, the first recessed part R1 may be formed in the first part P1 connected to the fourth surface S4, and the second part P2 adjacent to the first part P1 may be connected to the third surface S3. The second part P2 may be bent (or recessed) from the first part P1.

The first part P1 may be parallel to a plane defined by the first direction DR1 and the second direction DR2. A portion of the second part P2, a bending portion, may be inclined at a certain angle with respect to a plane defined by the first direction DR1 and the second direction DR2, and a flat surface portion of the second part P2 may be parallel to a plane defined by the first direction DR1 and the second direction DR2.

In the drawing, the bending portion is illustrated as being bent in a direction parallel to a normal direction to the first surface S1. However, embodiments are not limited thereto, and the bending portion may be bent at a certain angle with respect to the normal direction to the first surface S1.

The first recessed part R1 may be formed in a region overlapping the first part P1 in a first short side part S1-S, and the second recessed part R2 may be formed in a second short side part S2-S of a second surface S2.

In the drawing, the first recessed part R1 and the second recessed part R2 are illustrated as partially overlapping each other based on a cross section in the direction parallel to the normal direction to the first surface S1. However, embodiments are not limited thereto, and the first recessed part R1 and the second recessed part R2 may not overlap on the cross section.

As described with reference to FIG. 5A, in the second surface S2 of the mask frame MF, the second recessed part R2 may be formed in the second short side part S2-S. However, embodiments are not limited thereto. As described with reference to FIG. 5B, in the second surface S2 of the mask frame MF, the second recessed part R2 may be formed in the second short side part S2-S, and a fourth recessed part R4 may be formed in a second long side part S2-L.

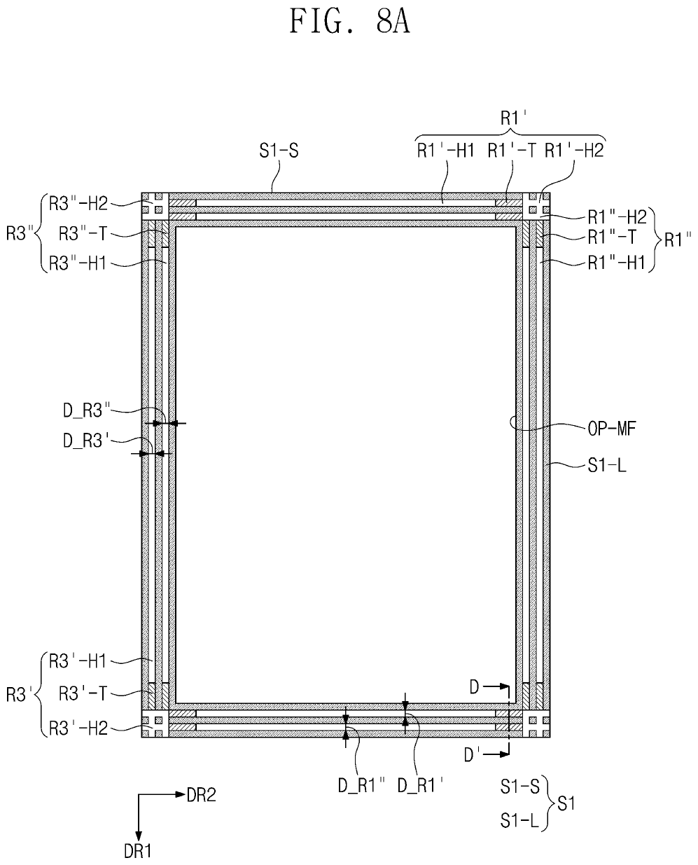

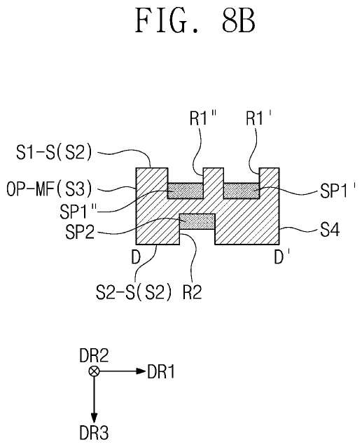

Like the configuration, which will be described below with reference to FIG. 8A, in which first recessed parts and third recessed parts are formed in a first surface, second recessed parts R2 and fourth recessed parts R4 may be formed in the second surface S2 of the mask frame MF and disposed in plurality in a direction spaced apart from a frame opening part OP-MF.

FIG. 8A is a schematic plan view of a mask frame according to an embodiment when viewed from the top. FIG. 8B is a schematic cross-sectional view of a mask frame according to an embodiment.

The same components as (or similar components to) those described with reference to FIG. 4 or 7 are denoted as the same/similar reference numbers or symbols, and redundant description is omitted for descriptive convenience.

Referring to FIG. 8A, first recessed parts R1′ and R1″ and third recessed parts R3′ and R3″ are formed in a first surface S1 of a mask frame MF according to an embodiment. For example, the first recessed parts R1′ and R1″ are formed in a first short side part S1-S of the first surface S1 in the second direction DR2, and the third recessed parts R3′ and R3″ are formed in a first long side part S1-L of the first surface S1 in the first direction DR1.

The first recessed parts R1′ and R1″ may be spaced apart from each other with a frame opening part OP-MF therebetween in a direction spaced apart from the frame opening part OP-MF. The third recessed parts R3′ and R3″ may be spaced apart from each other with the frame opening part OP-MF therebetween in the direction spaced apart from the frame opening part OP-MF.

For example, first support members may be provided to correspond to the number of the first recessed parts R1′ and R1″, and the same structure may apply to the third recessed parts R3′ and R3″.

For example, the first support members may be accommodated in all of the first recessed parts R1′ and R1″. However, embodiments are not limited thereto, and the first support members may be accommodated only in some of the first recessed parts R1′ and R1″.

In case that the first recessed parts R1′ and R1″ are formed, each of the first recessed parts R1′ and R1″ may have a width smaller than or substantially equal to the width of the first recessed part R1, which is described above, in case that one first recessed part R1 is disposed between the third surface S3 and the fourth surface S4. The same structure may apply to the third recessed parts R3′ and R3″.

Although not illustrated in the drawing, the same structure may apply to a second recessed part and a fourth recessed part.

Referring to FIG. 8B, in a second surface S2 of the mask frame MF, a second recessed part R2 may be formed in a second short side part S2-S.

For example, some of the first recessed parts R1′ and R1″ and a portion of the second recessed part R2 may overlap each other on a cross section perpendicular to an extension direction of the first recessed parts R1′ and R1″ and the second recessed part R2.

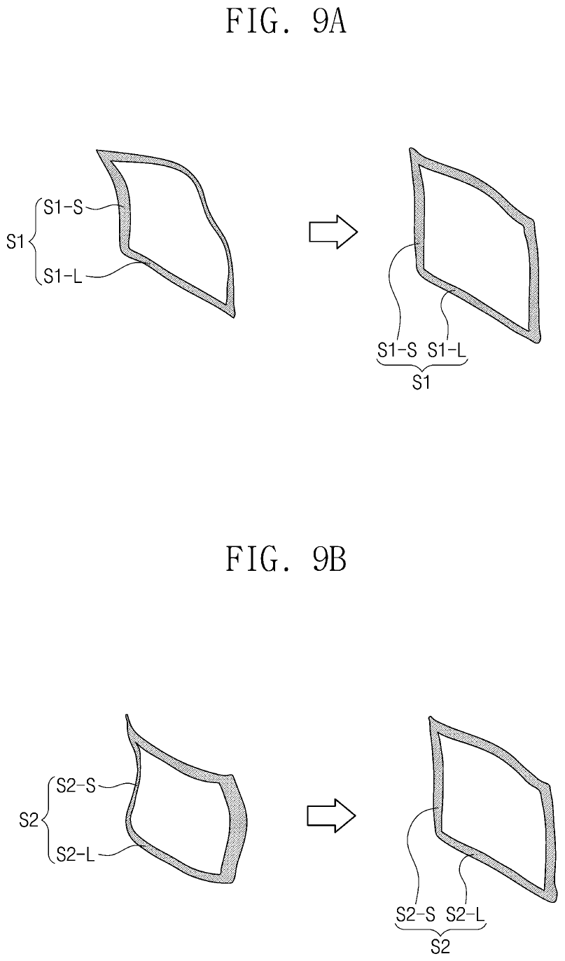

FIGS. 9A and 9B are schematic views illustrating a method for controlling anti-deformation of a mask frame according to an embodiment.

FIG. 9A illustrates a case, in which the mask frame MF is deformed to a shape bent (or curved) in the normal direction to the first surface S1 during the vertical loading of the mask frame MF, and a state in which the curling of the mask frame MF is controlled by disposing the support members SP1, SP2, SP3 and SP4 on the second surface S2 to provide tension in the direction opposite to the normal direction to the first surface S1. FIG. 9B illustrates a case, in which the mask frame MF is deformed to a shape bent (or curved) in the normal direction to the second surface S2 during the vertical loading of the mask frame MF, and a state in which the curling of the mask frame MF is controlled by disposing the support members SP1, SP2, SP3 and SP4 (see FIG. 3) on the first surface S1 to provide tension in the direction opposite to the normal direction to the second surface S2.

For example, during the vertical loading of the mask frame MF, the first support member SP1 or the third support member SP3 may be disposed on and may support the first short side part S1-S or the first long side part S1-L of the first surface S1 of the mask frame MF so that the deformation of the rear surface of the mask frame MF may be controlled. The second support member SP2 or the fourth support member SP4 may be disposed on and support the second short side part S2-S or the second long side part S2-L of the second surface S2 of the mask frame MF so that the deformation of the front surface of the mask frame MF may be controlled.

As described above, the deformation of the mask frame MF may be prevented in such a manner that the first to fourth support members SP1, SP2, SP3 and SP4 are accommodated in and coupled and fixed to the first to fourth recessed parts R1, R2, R3 and R4 (see FIG. 3).

The mask frame assembly, the mask assembly, and the deposition apparatus according to an embodiment may control the deformation of the front portion or the rear portion of the mask frame through the support members disposed on the front portion or the rear portion of the mask frame.

The mask frame assembly according to an embodiment, the mask assembly including the mask frame assembly, and the deposition apparatus including the mask assembly may control the deformation of the mask frame to ensure the accuracy of the position at which the light emitting pattern is formed.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A mask frame assembly comprising:
a mask frame including:
a first surface including:
a first long side part extending in a first direction,
a first short side part extending in a second direction intersecting the first direction, and
a first recessed part extending along the first long side part in the first direction or extending along the first short side part in the second direction,
a second surface opposite to the first surface, the second surface including:
a second long side part extending in the first direction,
a second short side part extending in the second direction, and
a second recessed part extending along the second long side part in the first direction or extending along the second short side part in the second direction, and
a third surface connected to the first surface and the second surface, the third surface defining a frame opening part;
a first support member disposed in the first recessed part; and
a second support member disposed in the second recessed part.

2. The mask frame assembly of claim 1, wherein:
the first recessed part comprises:
a first inner groove spaced apart from the frame opening part by a distance,
a first outer groove defined at opposite sides of the first inner groove, and
a first step defined between the first inner groove and the first outer groove; and
the second recessed part comprises:
a second inner groove spaced apart from the frame opening part by a distance,
a second outer groove defined at opposite sides of the second inner groove, and
a second step defined between the second inner groove and the second outer groove.

3. The mask frame assembly of claim 2, wherein a depth of the first inner groove and a depth of the second inner groove are greater than or substantially equal to a depth of the first outer groove and a depth of the second outer groove, respectively.

4. The mask frame assembly of claim 2, wherein
the first recessed part includes a plurality of first recessed parts,
the second recessed part includes a plurality of second recessed parts,
the plurality of first recessed parts or the plurality of second recessed parts are spaced apart from each other in a direction that is away from the frame opening part.

5. The mask frame assembly of claim 3, wherein the first recessed part and the second recessed part do not overlap each other on a cross section perpendicular to an extension direction of the first recessed part and the second recessed part.

6. The mask frame assembly of claim 1, wherein
the first recessed part is defined in the first short side part, and
the second recessed part is defined in the second short side part.

7. The mask frame assembly of claim 2, further comprising:
a third support member; and
a fourth support member, wherein
the first surface of the mask frame further includes a third recessed part accommodating the third support member and extending in a direction intersecting the first recessed part, and
the second surface of the mask frame further includes a fourth recessed part accommodating the fourth support member and extending in the second surface in a direction intersecting the second recessed part.

8. The mask frame assembly of claim 7, wherein:
a width of the first recessed part and a width of the third recessed part are different from each other; and
a width of the second recessed part and a width of the fourth recessed part are different from each other.

9. The mask frame assembly of claim 8, wherein:
a width of the first support member and a width of the third support member are different from each other; and
a width of the second support member and a width of the fourth support member are different from each other.

10. The mask frame assembly of claim 1, wherein:
the mask frame further comprises a fourth surface opposite to the third surface;
the first surface comprises:
a first part connected to the fourth surface, and
a second part adjacent to the first part, the second part including a portion bent to be connected to the third surface; and
the first recessed part is defined in the first part.

11. A mask frame assembly comprising:
a plurality of first support members and a plurality of second support members;
a mask defining a deposition opening part; and
a mask frame including:
a first surface facing the mask, the first surface including:
a first long side part extending in a first direction; and
a first short side part extending in a second direction intersecting the first direction, the first short side part in which the plurality of first support members are disposed,
a second surface opposite to the first surface, the second surface including:
a second long side part extending in the first direction; and
a second short side part extending in the second direction, the second short side part in which the plurality of second support members are disposed, and
a third surface connected to the first surface and the second surface, the third surface defining a frame opening part overlapping the deposition opening part,
wherein a second recessed part extends in the second direction, accommodates the plurality of second support members, and is defined in the second short side part.

12. The mask frame assembly of claim 11, wherein a first recessed part extends in the second direction, accommodates the plurality of first support members, and is defined in the first short side part.

13. The mask frame assembly of claim 12, wherein a thickness of each of the plurality of first support members and a thickness of each of the plurality of second support members are smaller than or substantially equal to a depth of the first recessed part and a depth of the second recessed part, respectively.

14. The mask frame assembly of claim 12, wherein the first recessed part comprises a plurality of first steps spaced apart from each other in an extension direction of the first recessed part, the plurality of first steps coupled to the plurality of first support members.

15. The mask frame assembly of claim 14, wherein the second recessed part comprises a plurality of second steps spaced apart from each other in an extension direction of the second recessed part, the plurality of second steps coupled to the plurality of second support members.

16. The mask frame assembly of claim 12, further comprising:
a plurality of third support members; and
a plurality of fourth support members, wherein
a third recessed part extends in the first direction, accommodates the plurality of third support members, and is defined in the first long side part, and
a fourth recessed part extends in the first direction, accommodates the plurality of fourth support members, and is defined in the second long side part.

17. The mask frame assembly of claim 16, wherein:
a width of the first recessed part and a width of the third recessed part are different from each other; and
a width of the second recessed part and a width of the fourth recessed part are different from each other.

18. The mask frame assembly of claim 11, wherein
the mask comprises a plurality of mask members, and
the plurality of mask members are arranged in the first direction or the second direction to be disposed on the mask frame.

19. The mask frame assembly of claim 11, further comprising:
a plurality of spacing sticks disposed on the mask frame.

20. A deposition apparatus comprising:
a deposition chamber that provides an inner space;
a mask frame including:
a first surface including:
a first long side part extending in a first direction, and
a first short side part extending in a second direction intersecting the first long side part,
a second surface opposite to the first surface, the second surface including:
a second long side part extending in the first direction, and
a second short side part extending in the second direction intersecting the second long side part, and
a third surface connected to the first surface and the second surface, the third surface defining a frame opening part;
a deposition member disposed at a first side of the mask frame;
a stage disposed at a second side of the mask frame and supported by the second surface of the mask frame;
a mask disposed between the mask frame and the deposition member at the first side of the mask frame and supported by the first surface of the mask frame;
a first support member disposed in the first short side part; and
a second support member disposed in the second short side part.

21. The deposition apparatus of claim 20, wherein the first support member and the second support member extend in the first direction.

22. The deposition apparatus of claim 21, wherein
a first recessed part accommodates the first support member, and is defined in the first short side part, and
a second recessed part accommodates the second support member, and is defined in the second short side part.

23. The deposition apparatus of claim 22, wherein:
a plurality of first steps are coupled to the first support member, and are defined in the first recessed part in an extension direction of the first recessed part; and
a plurality of second steps are coupled to the second support member, and are defined in the second recessed part in an extension direction of the second recessed part.

24. The deposition apparatus of claim 22, further comprising:
a third support member extending in a direction intersecting the first direction, and disposed in the first long side part; and
a fourth support member extending in a direction intersecting the first direction, and disposed in the second long side part.

25. The deposition apparatus of claim 24, wherein
a third recessed part accommodates the third support member, and is defined in the first long side part,
a fourth recessed part accommodates the fourth support member, and is defined in the second long side part,
the third recessed part includes a plurality of third steps coupled to the third support member and disposed in an extension direction of the third recessed part, and
the fourth recessed part includes a plurality of fourth steps coupled to the fourth support member and disposed in an extension direction of the fourth recessed part.

26. The deposition apparatus of claim 20, wherein an extension direction of the first short side part and the second short side part has a tilt angle of about 45 degrees with respect to a normal direction to a bottom surface of the deposition chamber.
